(19) United States
(12) Patent Application Publication
(10) Pub. No.: US 2005/0141179 A1
(43) Pub. Date: Jun. 30, 2005

(54) Combined computer and communications apparatus

(75) Inventor: Martin P. Riddiford, London (GB)

Correspondence Address: Breiner & Breiner, L.L.C., P.O. Box 19290, Alexandria, VA, 22320-0290, US

(73) Assignee: Therefore Limited, London (GB)

(21) Appl. No.: 10/992,835

(22) Filed: Nov. 22, 2004

(30) Foreign Application Priority Data
Nov. 21, 2003 (GB) 0327201.0

(51) Int. Cl. H05K 5/00; B26B 27/00

(52) U.S. Cl. 361/681

(57) ABSTRACT

Combined computer and communications apparatus is described which has an improved hinging arrangement between two casing halves (1, 2). By enabling each casing half to hinge around one of two spaced parallel hinge axes, with a hinge including an articulated linkage (28, 30) having its ends pivoted around the two hinge axes, improved snap action open or closed may be achieved. The articulated linkage has two pivots (21) intermediate its ends, each pivoted to one of the casing halves (1, 2). Spring means (20) urge the casing halves together or into a coplanar arrangement.

### FIELD OF THE INVENTION

This invention relates to combined computer and communications apparatus, for example apparatus bringing together the features of a palmtop computer, personal digital assistant (PDA) or the like on the one hand and of a mobile telephone on the other.

### BACKGROUND OF THE INVENTION

Apparatus of this general type is known and described, for example, in PCT Publication WO 98/19226. This describes combined computer and communications apparatus consisting of a two-part casing where the two parts of the casing are hinged together. When the two parts are folded so that one overlies the other, the unit can act as a mobile telephone. When the two halves are folded apart to lie side-by-side, this exposes a full alphanumeric keyboard of conventional landscape shape above which is arranged a screen display of conventional type. In one of the embodiments illustrated, the screen display is located in one of the casing halves and the other casing half has a window which, when the two halves are folded together, overlies the screen, enabling the screen to be viewed when the device is folded. The screen can then (when the device is being used as a mobile telephone unit) provide the conventional type of display well-known in mobile telephones. The window may be relatively small if the screen display for mobile telephone use can be accommodated on less than the full screen, with the larger screen area being viewable only when the device is unfolded and the full alphanumeric keyboard exposed for use below it.

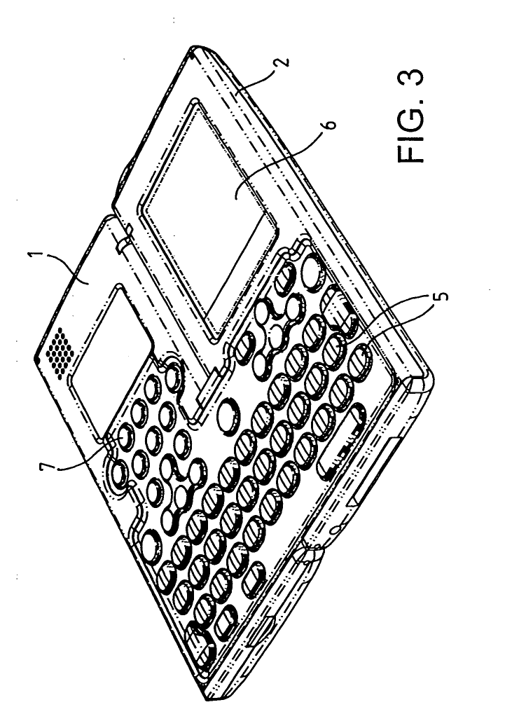

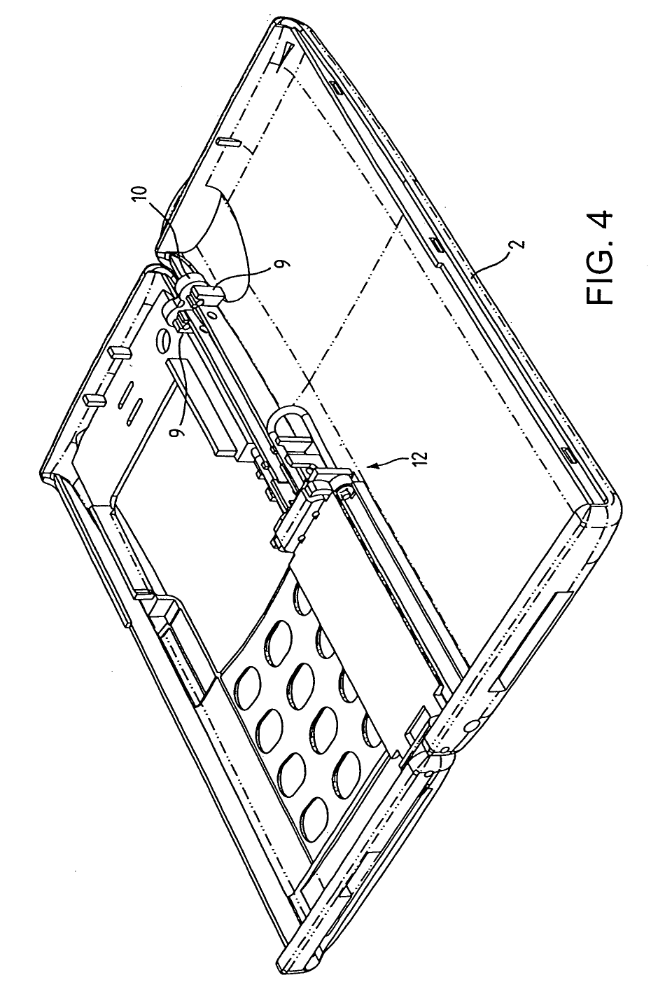

As disclosed in the specification referred to above, the hinging arrangement between the two halves is preferably one which has two hinge axes, parallel and spaced slightly apart from one another. This type of construction enables a reasonable folding action to be achieved as illustrated in FIGS. 3 and 4 of the specification noted, but the mechanism there illustrated is not one which gives a particularly satisfactory feel to the unfolding or closing manipulation. The published specification indicates that springs may be associated with the pivoting of the sections of the casing to urge the casing sections to lie preferentially in the opened out flat position, or folded together, but no constructional details are provided as to how this might be achieved.

### OBJECTS OF THE INVENTION

A principal object of the present invention is, by appropriate configuration of the hinge members and springs to achieve a satisfactorily positive action.

A further object is to provide improved keyboard arrangements for such apparatus and to accommodate developments in such apparatus, particularly relating to the incorporation of camera apparatus therein, in convenient fashion.

### GENERAL DESCRIPTION OF THE INVENTION

Thus, according to a first feature of the present invention there is provided combined computer and communications apparatus incorporated in a casing comprising two halves pivotally hinged together, wherein the hinging arrangements include a link member to which each of the casing halves is pivotally attached enabling it to hinge around one of two spaced parallel hinge axes, and characterised by an articulated linkage having its ends pivoted around the two hinge axes, having two intermediate pivots each pivoted to one of the casing halves and by spring means urging the casing halves together, or into a coplanar position.

By constructing the hinge and linkage arrangements between the two halves in this way, and, in particular, by the appropriate selection of spring configuration and force, the unit may be enabled to adopt one or two positions, conveniently simply referred to hereinafter as folded and flat, where, in each case, the casing halves are biased strongly towards the folded or flat conditions, but where the biasing force of the springs on the casing halves is materially reduced when the casing halves are in an intermediate position between folded and flat. By careful design, it can be achieved that the biasing force operates only effectively at the ends of the travel from one condition to the other. For example, when the angle between the two halves of the casing (when folded) is 0°, the biasing may be strong to hold the two halves of the casing folded one adjacent the other, and that bias may be effective as the two halves of the casing are pivoted apart from one another until the angle between them is, say, 15°. Thereafter, the bias towards folding together may be reduced, or effectively insignificant, only coming into force again as the angle between the casing halves approaches 165°, i.e. Leaking the final 15° of travel as a range in which the two casing halves are increasingly biased to the flat position where one is essentially coplanar with the other.

A wide variety of mechanical arrangements may be devised to effect such a type of movement. One variety is illustrated in the Examples described in more detail below.

As illustrated in the published specification referred to above, the alphanumeric keyboard is of standard form consisting of four rows, the topmost row being substantially composed of numeric keys followed by three rows of alphabetic keys. This takes up a substantial amount of space and, in addition, the provision of the number keys in a single row is less than convenient, for example, when the device is to be used in calculator mode.

According to a further feature of the present invention, there is provided folding computer/communications apparatus consisting of two casing halves hinged one to another such that the two casing halves can be arranged side-by-side to expose an alphanumeric keyboard adjacent which is a viewing screen, and wherein the keyboard arrangement is characterised by a plurality of rows of alphabetic characters extending across both casing halves and, located adjacent those rows, and in one casing half only, a substantially low aspect ratio rectangular numeric keypad array.

Preferably the alphabetic rows are of standard Querty configuration and the rectangular array is of standard telephone pad configuration, i.e. four columns and three rows corresponding to the ten number keys 0 to 9 and conventional star and hash keys.

This arrangement is particularly user-friendly and convenient and matches the compactness of such folding computer/communications devices in a practical fashion. Other press buttons/keys can, of course, also be arranged, for example function keys and the like. In a particularly preferred arrangement, between the screen and the rows of alphabetic keys, there is located some form of navigation button, for example of known joystick or quadrant type.

In recent years, technology has advanced sufficiently to enable miniaturised video cameras to be incorporated in mobile telephony handsets. These enable users to send to others images as well as to communicate via text messaging or the spoken word. The conventional arrangement, however, is somewhat inconvenient in that the field of view of the camera is either directed away from the person viewing the conventional mobile telephone unit screen, or towards that person. The latter arrangement is particularly inconvenient where the user wishes to send someone an image of something other than the user's face where it is necessary (because the screen acts to indicate what the camera is looking at) to hold the unit above one's head, or to one side of it, and to have one's back to the scene being viewed.

In accordance with a further feature of the present invention, a miniaturised video camera is incorporated into combined computer/communications apparatus of the type described above in the casing portion which incorporates a window and not in the casing portion which incorporates the screen. The scene viewed by the miniaturised video camera is thus one which can be displayed on the screen and which, when the unit is in the flat condition, can be seen through the window. The window thus acts as a viewfinder in addition to the conventional display on the screen of what the camera is looking at. This enables a much more convenient and user-friendly manipulation of the device to occur. The device, unfolded flat, is simply held up in front of the user and the scene viewed by the camera can then be seen framed by the window as well as displayed on the adjacent screen. Both camera and user are looking in the same direction, it is then very easy and natural to adjust the orientation of the unit so that the desired picture is captured by the video camera. Because the user is looking at the scene, the window in the casing acts similarly to a standard camera viewfinder. As when using a telescope, the user simply fixes his gaze on to the scene it is desired to make the device “see”, and then inserts the device between his eye and the scene, adjusting the pan and tilt of the device to produce the desired image of the scene on the display screen, whereafter the “take picture” button or the like can be actuated to capture the image of the scene.

If, of course, the user does wish to use the camera to produce a “self-portrait”, then the device may simply be folded, thus directing the camera field of view towards the user's head and the user can see the image of his or her head in the screen through the window (though looking through the window in the opposite direction to when the device is flat).

In combined computer and communications apparatus as described above, one casing half has half of the full keyboard on one side of it and a standard telephone keypad on the other. In order to give an overall unit which has balance, i.e. the two casing halves are of substantially equal size and weight, it is convenient to mount the battery pack power supply in that casing half, keeping the other available for the screen display and most of the electronics. In order to achieve this, and this constitutes a further feature of the invention, the casing half having a keypad on both sides is configured to receive a battery pack between the two keypads, the battery pack being insertable and removable in a direction parallel to the plane of the two keypads. This may be achieved by providing a battery pack receptacle, preferably accessible from the end of the casing remote from the window in it, into which a battery pack may be slid, either as such or by providing a movable slide akin to a shallow drawer which, when opened, allows a battery pack to be placed in it or removed from it and, when closed, causes terminals on the battery pack to contact a set of contacts mounted within that casing half.

### SPECIFIC DESCRIPTION OF THE PREFERRED EMBODIMENTS

### The invention is illustrated by way of example with reference to the accompanying drawings in which:

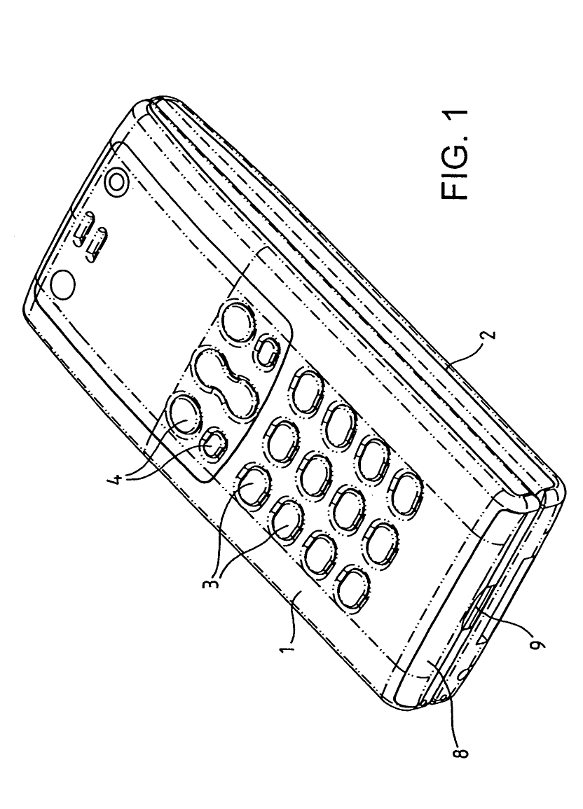

FIG. 1 is a perspective view of combined computer and communications apparatus in accordance with the present invention, in folded condition;

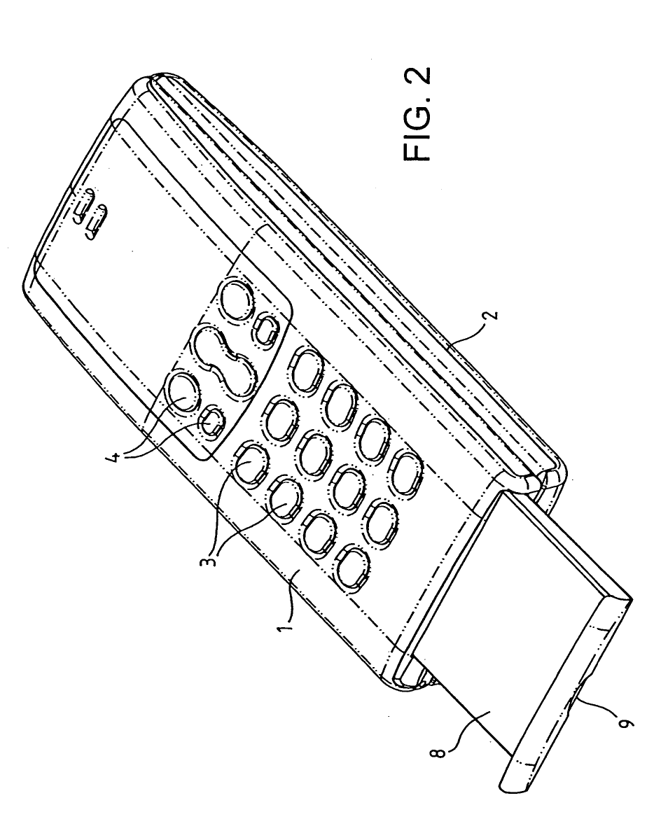

FIG. 2 is a view similar to FIG. 1 showing an extended battery pack receptacle;

FIG. 3 is a plan view of the apparatus of FIG. 1 when opened out flat showing the arrangement of the keyboard visible when the apparatus is unfolded;

FIG. 4 is a perspective view of the casing of the apparatus of FIG. 1 with the keyboard and electronic components removed, showing the hinging arrangements;

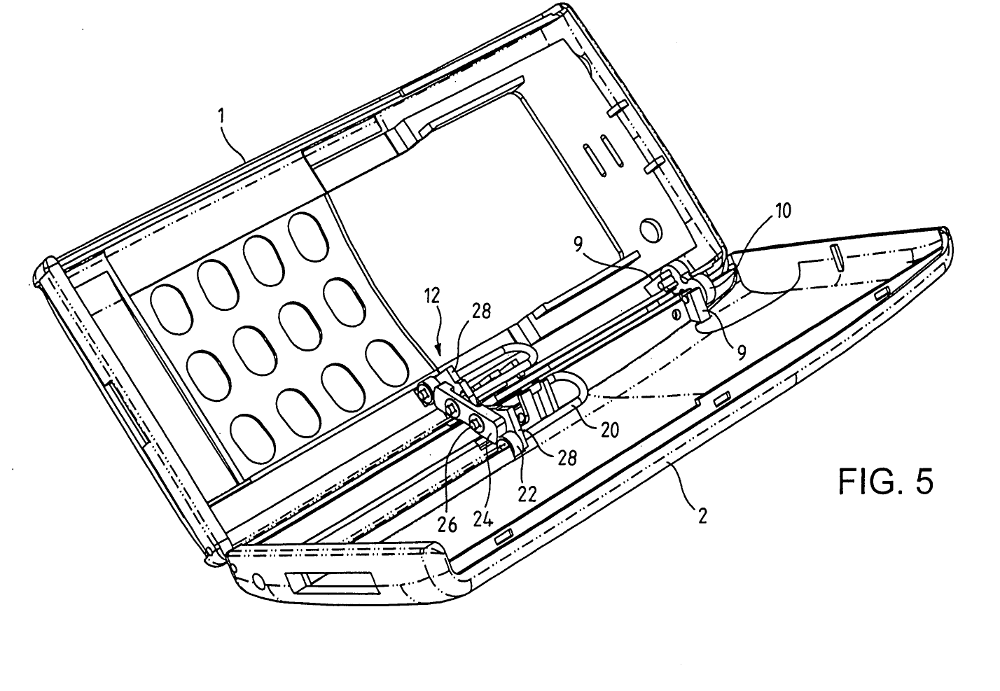

FIG. 5 is a view similar to FIG. 4, but showing the components there shown in a different relative position of the two casing halves;

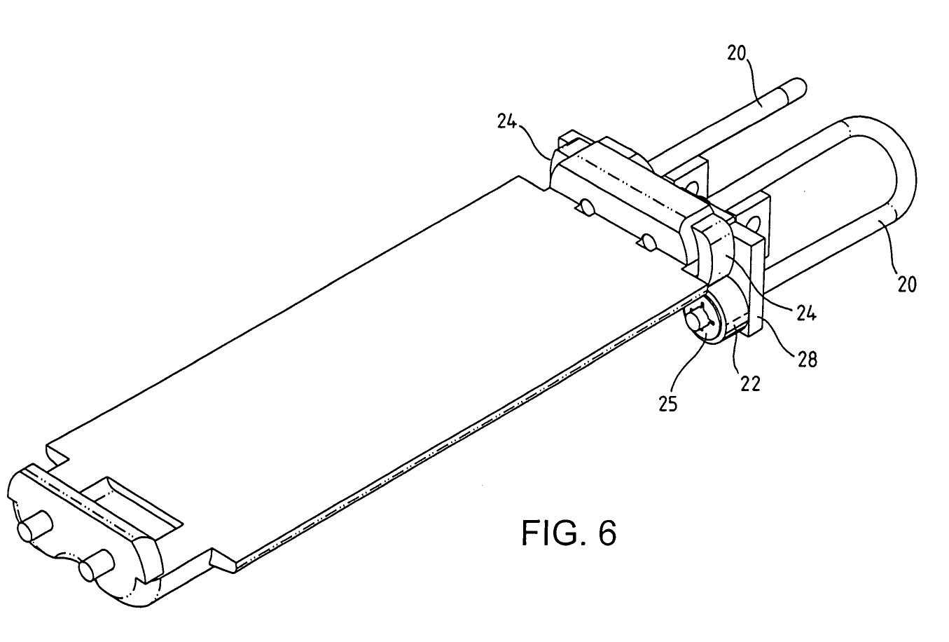

FIG. 6 is a perspective view on an enlarged scale of the spring-loaded hinge mechanism between the casing halves;

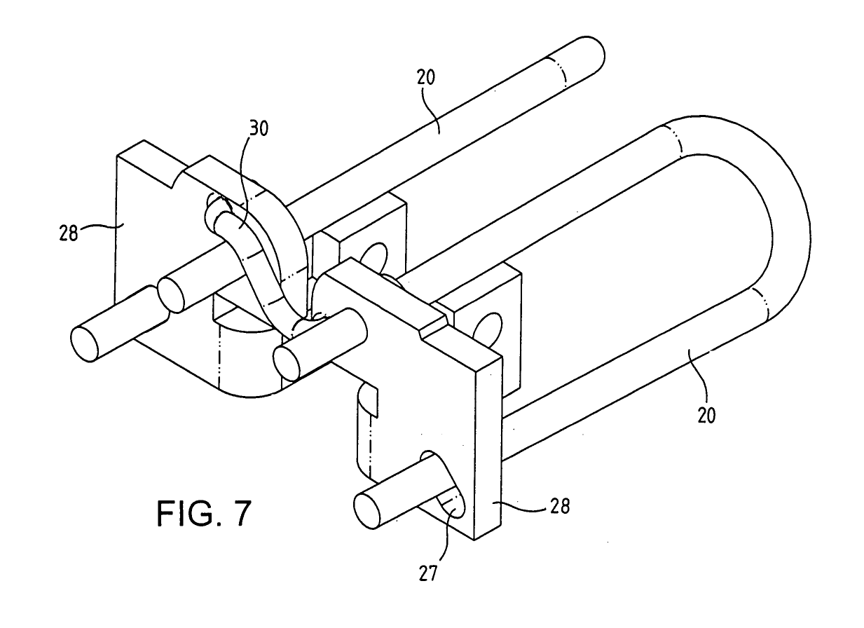

FIG. 7 is a perspective view of part of the hinge mechanism of FIG. 6;

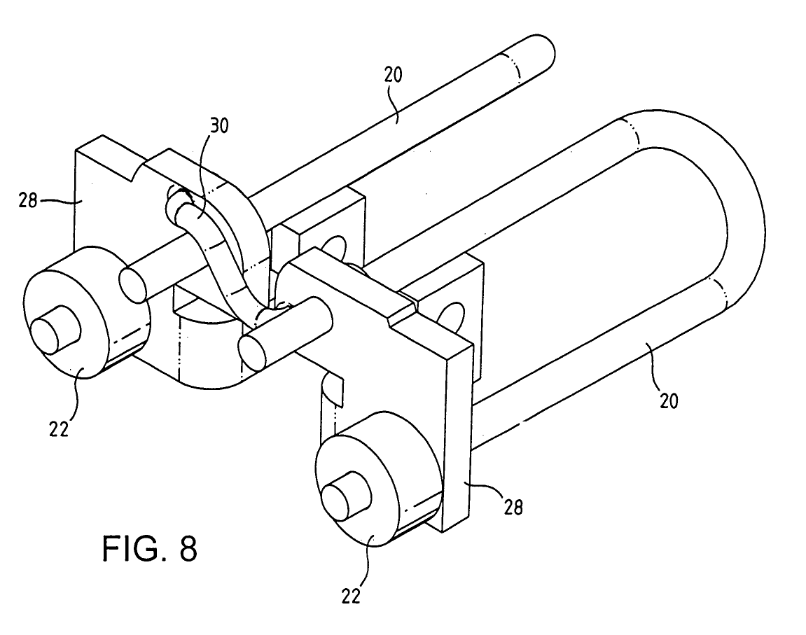

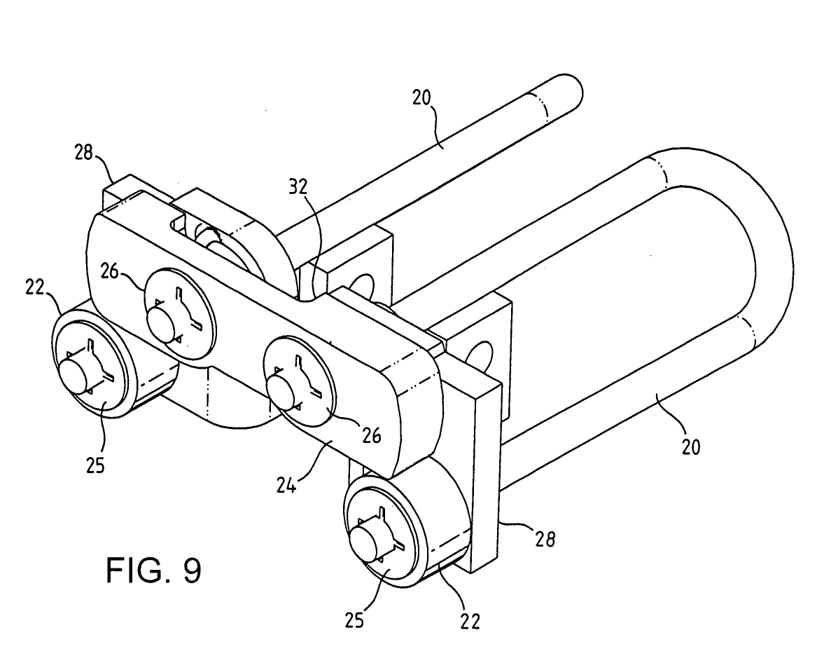

FIGS. 8 and 9 are views similar to FIG. 7 showing stages in the assembly of the hinge mechanism;

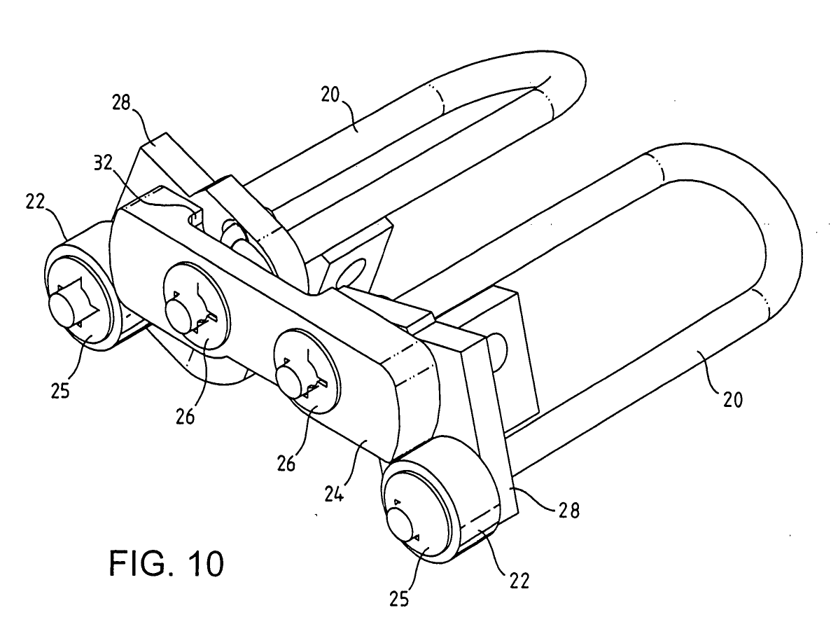

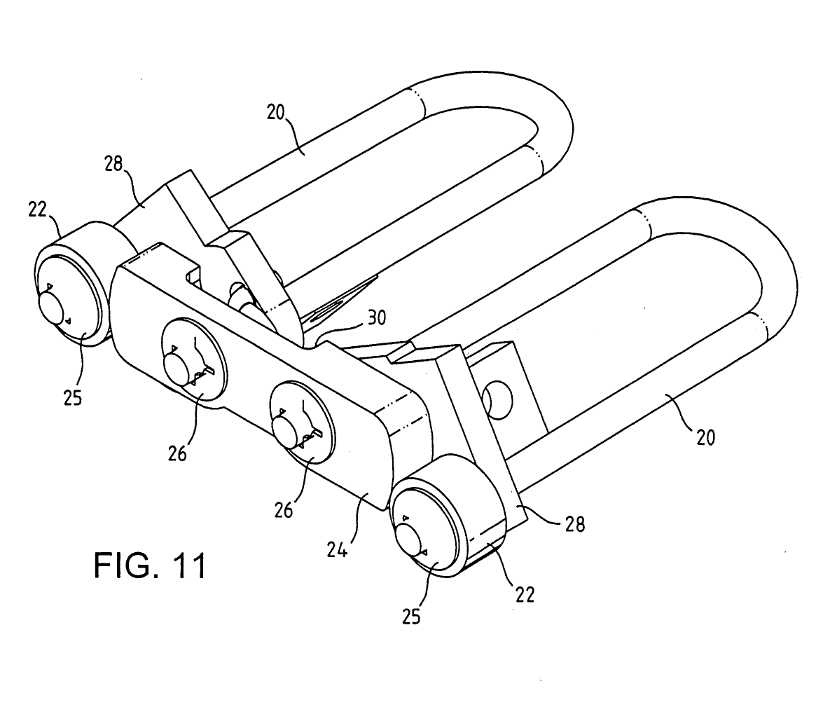

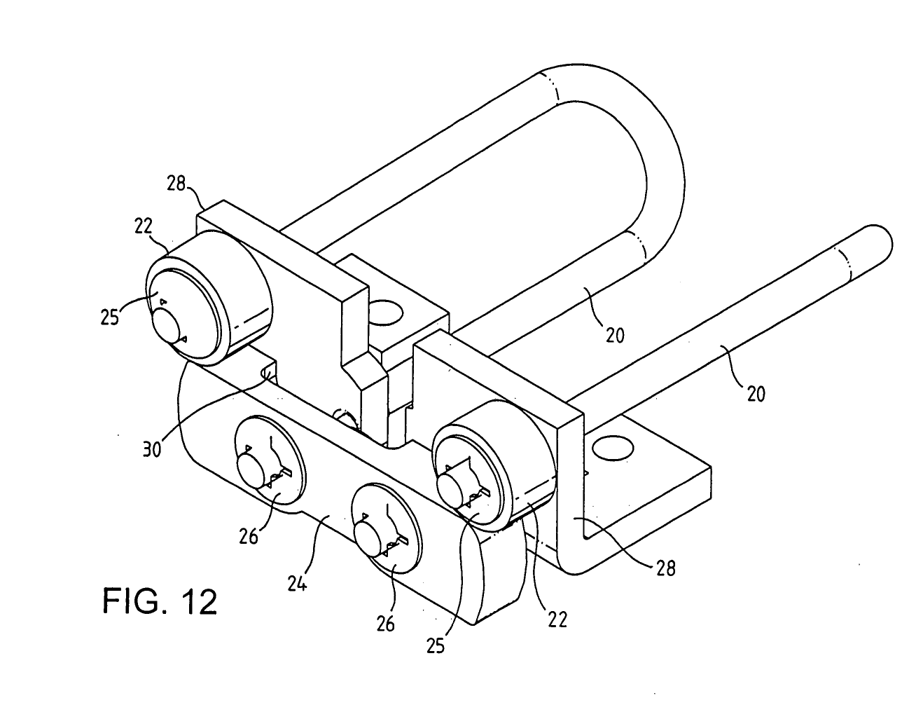

FIGS. 10 to 12 show the relative positions of the hinge mechanism components as the casing is folded from flat (FIG. 9) to folded (FIG. 12);

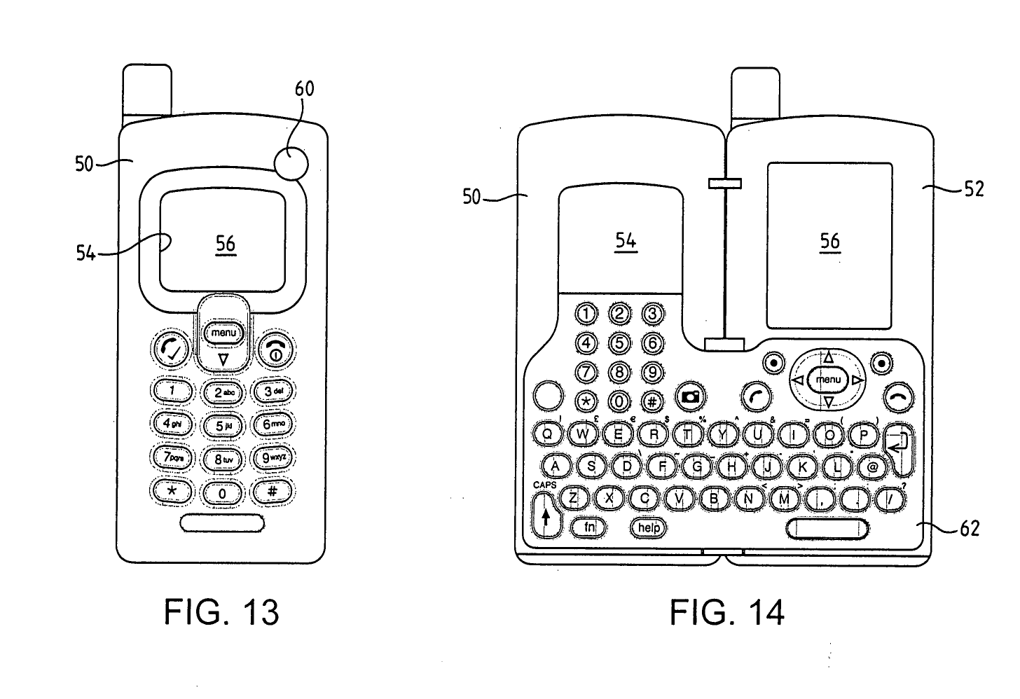

FIGS. 13 and 14 are plan views of a combined computer and communications apparatus in folded and flat conditions respectively;

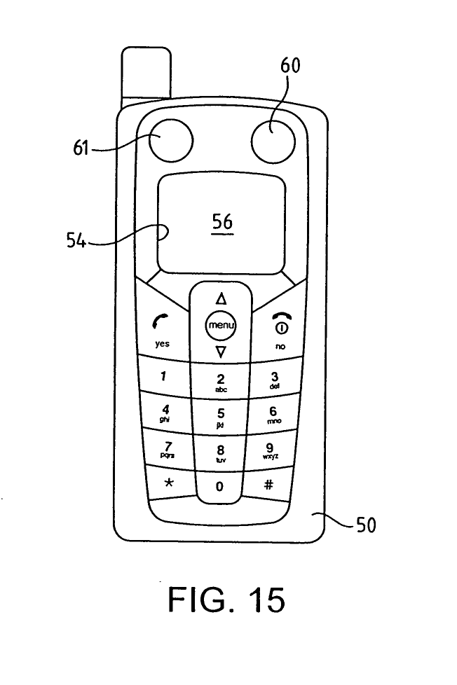

FIG. 15 is a view similar to FIG. 13 but showing an alternative keypad arrangement, and

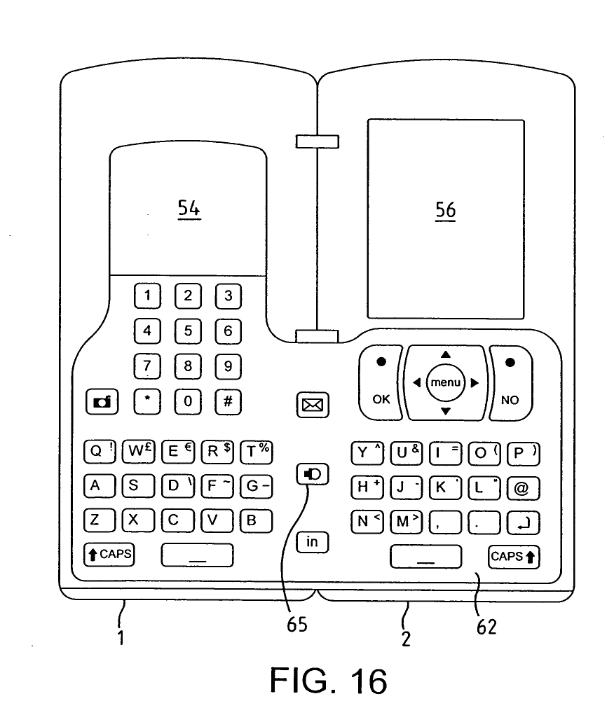

FIG. 16 is a view similar to FIG. 14 but showing an alternative keypad arrangement.

Referring to the drawings, FIGS. 1 to 4 show apparatus according to the present invention which has a casing consisting of two main portions, an upper portion 1 and a lower portion 2, as shown in FIG. 1 which, when folded apart, are on the left and right sides of the apparatus as shown in FIGS. 3 and 4. As can be seen in FIG. 1, the outside of casing portion 1 carries a standard keypad consisting of a number of buttons 3 which may conventionally be the 0 to 9, * and # keys conventional on a mobile telephone unit. Above the keys 3, as shown in FIG. 1, are other operation keys 4, again in a conventional arrangement.

As shown in FIG. 2, the apparatus may be powered by a battery pack (not shown) which is placed on a slide 8 which can be pulled out from casing portion 1 by engagement of a thumbnail or small coin in a slot or notch 9. When slid back in, contacts on the end of the battery pack make contacts with contacts internally of casing portion 1 to power the apparatus.

When the apparatus of the invention is unfolded as shown in FIG. 3, a full Qwerty keyboard is exposed and in addition the full extent of a screen 6 mounted in casing part 2 is then visible. Above the left-hand end of the Qwerty keyboard, as seen in FIG. 3, is a numeric keypad indicated generally at 7.

FIG. 4 shows the casing portions 1 and 2 with the operative parts, i.e. the keypads, screens, etc. removed. This enables the hinging mechanism between casing portions 1 and 2 to be clearly discerned and the way in which the casing halves may be folded together to be seen. Each casing half 1, 2 has a post 9 moulded in it which has at its upper end a cylindrical socket. Press fitted into the cylindrical socket is one of the prongs of an integrally moulded plastics hinge piece 10, the prongs defining the hinge axes about which casing portions 1 and 2 may be rotated. Lying straddling these hinge axes is a resiliently sprung hinge member generally indicated at 12 which is shown in substantially more detail in FIGS. 6 to 12.

Referring to FIG. 5 and FIGS. 6 to 12, it can be seen that the hinge mechanism 12 comprises a pair of U-shaped springs 20. One leg of each U-shaped spring 20 has located on its free end a roller 22 which is biased by means of spring member 20 into contact with a link piece 24, and held on the end of spring 20 by a spire clip 25. The other ends of spring members 20 pass through link 24 and are held captive to that link by a pair of spire clips 26. The leg of each spring member 20 carrying the roller 22 passes through a slot 27 in a plate 28 in each case forming a part of casing member 1 or 2 through which both legs of spring member 20 pass, the leg bearing roller 22 passing through the slot 27 and the leg passing through link 24 passing through a circular aperture in plate 28. Plates 28 are also linked together by a wire link 30 which is pivoted in a circular hole in each plate 28, and which is held captive against the plates 28 by link 24, the rear side of which, as seen in FIGS. 9 to 12, is relieved at 32.

FIGS. 9 to 12 show the sequence of movement of these various parts when the casing portions 1,2 are swivelled around one another to move the unit from a fully open flat unfolded position, as shown in FIG. 4, through the part folded position shown in FIG. 5, to the closed position, where the parts lie as shown in FIG. 12. Because of the shaping of the ends of link 24, around which each of the rollers 22 rolls, the initial and final parts of the movement from flat to folded or vice versa, are spring loaded by springs 20, urging the casing parts to folded or flat condition. Between times, the roller is going round the end of the link 24, and there is only slight bias towards the open or folded condition.

FIGS. 13 and 14 are front views of a combined computer and communications device, folded and flat respectively, showing its positions in use as a mobile telephone unit and as a camera/organiser respectively. As shown, the casing parts are denoted 50, 52 and they may be hinged together as detailed above. Casing part 50 has a window 54, through which part of a display screen 56 is visible in the folded condition. When two such units are used as mobile telephone units, each speaker may, with an appropriate communications system provided by the telephone provider, see the caller at the “other end”, if the unit is held in front of each caller, as casing part 50 houses a miniature video camera 60.

If the caller wishes to show the other caller e.g. the view he/she is seeing, then the casing is unfolded, to the position shown in FIG. 14, and the scene seen by the camera 60 is then visible through the window 54, which thus acts as a viewfinder.

If the unit is to be used as an organiser, then the unit is laid flat so that the fully Qwerty keyboard, denoted 62, is exposed, as is the full extent of screen 56. The programming of the electronics in the unit can be arranged so that when it is being used as a mobile telephone, the display needed for straightforward operation (and person called display if enabled) is positioned on that part of screen 56 visible through window 54.

FIG. 15 is a view similar to FIG. 13, but showing an alternative keypad layout for use when the unit is being used as a mobile telephone. This also shows, in addition to camera 60, a flash unit 61 for illuminating the scene when the user wishes to capture a “shot” and send it.

FIG. 16 shows an alternative keyboard arrangement. In this case, though the Qwerty keyboard 62 is still a folding one, the two groups of alphabetic keys have been split apart down the middle. This is more convenient for “two-thumb” keyboard input, which may be employed by some users, particularly if text is to be entered while holding the apparatus in both hands rather than laying it down on a support surface.

A particular feature of the keyboard arrangement of FIG. 16 is the provision of a “mute” button 65 in the centre. This is of particular value when the apparatus is programmed, when open, to move to a “loudspeaker” mode, as normally if the apparatus is unfolded while a conversation is carried on, it is inconvenient to keep holding the apparatus to the user's ear. However, there can be circumstances, e.g., when the apparatus is being used in a train compartment, where this is undesired, so a mute button can over-ride the automatic changeover to loudspeaker mode when the casing is folded to lie flat and expose the Qwerty keyboard.

1. Combined computer and communications apparatus incorporated in a casing comprising two halves pivotally hinged together, wherein the hinging arrangements include a link member to which each of the casing halves is pivotally attached enabling it to hinge around one of two spaced parallel hinge axes, and characterised by an articulated linkage having its ends pivoted around the two hinge axes, having two intermediate pivots each pivoted to one of the casing halves and by spring means urging the casing halves together, or into a coplanar position.

2. Apparatus according to claim 1 wherein, by the appropriate selection of spring configuration and force, the unit may be enabled to adopt one of two positions, folded or flat, where, in each case, the casing halves are biased strongly towards the folded or flat conditions, but where the biasing force of the springs on the casing halves is materially reduced when the casing halves are in an intermediate position between folded and flat.

3. Apparatus according to claim 1 or 2 and including a miniaturised video camera incorporated into the casing portion which incorporates a window, allowing the window to act as a viewfinder.

4. Computer and communications apparatus according to claim 1 or 2 wherein the casing half having a keypad on both sides is configured to receive a battery pack between the two keypads, the battery pack being insertable and removable in a direction parallel to the plane of the two keypads.

5. Apparatus according to claim 4 and including a battery pack receptacle, accessible from the end of the casing remote from the window in it, into which a battery pack may be slid, either as such or supported on a movable slide.

6. Folding computer/communications apparatus consisting of two casing halves hinged one to another such that the two casing halves can be arranged side-by-side to expose an alphanumeric keyboard adjacent which is a viewing screen, and wherein the keyboard arrangement is characterised by a plurality of rows of alphabetic characters extending across both casing halves and, located adjacent those rows, and in one casing half only, a substantially low aspect ratio rectangular numeric keypad array.

7. Apparatus according to claim 6 wherein the alphabetic rows are of standard Querty configuration and the rectangular array is of standard telephone pad configuration.

8. Apparatus according to claim 6 or 7 wherein between the screen and the rows of alphabetic keys, there is located a navigation button of joystick or quadrant type.

9. Apparatus according to claim 6 or 7 and including a miniaturised video camera incorporated into the casing portion which incorporates a window, allowing the window to act as a viewfinder.

10. Computer and communications apparatus according to claim 6 or 7 wherein the casing half having a keypad on both sides is configured to receive a battery pack between the two keypads, the battery pack being insertable and removable in a direction parallel to the plane of the two keypads.

11. Apparatus according to claim 10 and including a battery pack receptacle, accessible from the end of the casing remote from the window in it, into which a battery pack may be slid, either as such or supported on a movable slide.
